(19) United States
(12) Patent Application Publication
(10) Pub. No.: US 2024/0312890 A1
(43) Pub. Date: Sep. 19, 2024

(54) SEMICONDUCTOR DEVICE ASSEMBLIES WITH CROSS-STACK STRUCTURES, AND ASSOCIATED METHODS

(71) Applicant: Micron Technology, Inc., Boise, ID (US)

(72) Inventors: Kelvin Tan Aik Boo, Singapore (SG); Hong Wan Ng, Singapore (SG); See Hiong Leow, Singapore (SG); Ling Pan, Singapore (SG); Seng Kim Ye, Singapore (SG); Chin Hui Chong, Singapore (SG)

(21) Appl. No.: 18/443,166

(22) Filed: Feb. 15, 2024

Related U.S. Application Data
(60) Provisional application No. 63/452,416, filed on Mar. 15, 2023.

(51) Int. Cl. H01L 23/498; H01L 23/00; H01L 23/31; H01L 25/00; H01L 25/065

(52) U.S. Cl. CPC H01L 23/49838; H01L 23/3128; H01L 24/32; H01L 24/48; H01L 24/73; H01L 25/0652; H01L 25/50; H01L 2224/32225; H01L 2224/48145; H01L 2224/48227; H01L 2224/73215; H01L 2924/181; H01L 2924/19011

(57) ABSTRACT

At least one embodiment of a semiconductor device assembly include a cross-stack substrate can comprise an assembly substrate including an upper surface, a first and second die stack at the upper surface, and a cross-stack substrate spaced from the upper surface. The first and second die stacks can each include multiple semiconductor dies in electric communication with the assembly substrate, and the cross-stack substrate can be coupled to and extending between a first and a second semiconductor die of the first and second die stacks, respectively. A passive semiconductor component can be carried by the cross-stack substrate, and can be in electric communication with the assembly substrate. Further, the passive semiconductor component can be in electric communication with the first semiconductor die of the first die stack exclusively via the assembly substrate.

### CROSS-REFERENCE TO RELATED APPLICATION(S)

The present application claims priority to U.S. Provisional Patent Application No. 63/452,416, filed Mar. 15, 2023, the disclosure of which is incorporated herein by reference in its entirety.

### TECHNICAL FIELD

The present technology generally relates to semiconductor device assemblies. In particular, the present technology relates to semiconductor device assemblies with cross-stack structures.

### BACKGROUND

Microelectronic devices, such as memory devices and microprocessors, and other electronics typically include one or more semiconductor devices and/or components attached to a substrate and encased in a protective covering. The devices and/or components include at least one functional feature, such as memory cells, processor circuits, or interconnecting circuitry, etc., on or within the devices and/or components. Each device and/or component commonly includes an array of small bond pads electrically coupled to the functional features for interconnection with other devices and/or components. For example, these interconnections can be from the devices and/or components to the substrate, and/or for interconnections routed within the substrate.

Manufacturers are under increasing pressure to reduce the space occupied by these devices and components while simultaneously increasing the capacity and/or speed of operation for the resulting semiconductor device assemblies. However, as devices and components shrink, manufacturers face design constraints for locating components on a semiconductor assembly or package substrate. Additionally, providing traces (e.g., routings) within the substrate for these components that adequately support their operation and follow efficient routes (e.g., by not extending along indirect and/or excessively long routes) similarly presents design challenges. The inability to include desired components and using inefficient traces between included components can hinder device and/or component functionality, limiting the capacity and speed of the resulting assemblies.

### BRIEF DESCRIPTION OF THE DRAWINGS

FIG. 1 is a side view of a semiconductor device assembly including a cross-stack structure, configured in accordance with some embodiments of the present technology.

FIG. 2 is a cross-sectional top view of a semiconductor device assembly including a cross-stack structure, configured in accordance with some embodiments of the present technology.

FIG. 3 is a side view of a semiconductor device assembly including a cross-stack structure, configured in accordance with some embodiments of the present technology.

FIG. 4 is a cross-sectional top view of a semiconductor device assembly including a cross-stack structure, configured in accordance with some embodiments of the present technology.

FIG. 5 is a side view of a semiconductor device assembly including a cross-stack structure, configured in accordance with some embodiments of the present technology.

FIG. 6 is a cross-sectional top view of a semiconductor device assembly including a cross-stack structure, configured in accordance with some embodiments of the present technology.

FIG. 7 is a side view of a semiconductor device assembly including a cross-stack structure, configured in accordance with some embodiments of the present technology.

FIGS. 8-11 illustrate a process for manufacturing a semiconductor device assembly including a cross-stack structure, in accordance with some embodiments of the present technology.

FIG. 12 is a flow diagram illustrating a process for producing a semiconductor device assembly including a cross-stack structure, in accordance with some embodiments of the present technology.

FIG. 13 is a schematic diagram illustrating a semiconductor device assembly incorporating the present technology, configured in accordance with some embodiments of the present technology.

The drawings have not necessarily been drawn to scale. Similarly, some components or operations can be separated into different components or combined into a single assembly in some implementations of the present technology. While the technology is amenable to various modifications and alternative forms, specific implementations have been shown by way of example in the drawings and are described in detail below.

### DETAILED DESCRIPTION

Traditionally, semiconductor device assemblies can include active components and passive components coupled to a surface of a semiconductor substrate, or a semiconductor assembly or package device. Active components can generally include elements like semiconductor devices and/or dies that can process and/or store information input thereto and provide an output therefrom. In contrast, passive components can generally include elements like resistors, capacitors, inductors, ferrite beads, and/or other similar building-block components of semiconductor device assemblies. These passive components generally cannot process and/or store information to the same capacity as active components, if at all, but instead are included within active components, or assemblies more broadly, to assist operation of the active components (e.g., provide power, clean noise, control operating features, etc.). However, the size of passive components, and the substrate routings supporting their operation, can occupy space that provides greater value to the assembly (e.g., capacity, speed, etc.) if occupied by an active component.

The present technology relates to semiconductor assemblies with semiconductor device stacks including structures extending therebetween. These structures can be cross-stack structures (e.g., cross-stack substrates) spaced from an assembly substrate, and can carry passive and/or active components thereon. In some embodiments, these components can be components relocated from the assembly substrate to the cross-stack structure, thereby freeing space on and/or within the assembly substrate, among other benefits. By freeing space on and/or within the assembly substrate, the assembly can include additional active and/or passive components and routings therein, allowing for increased operation capacity, speed, and signaling integrity, among other performance improvements.

The cross-stack structures can also provide beneficial physical improvements to the assembly. For example, newly-found free space on and/or within the assembly substrate can be eliminated from the assembly. That is, portions of the assembly substrate previously filled by components now carried by the cross-stack structure can be removed, reducing an overall footprint of the assembly. Further, the cross-stack structure can provide improved structural integrity to the assembly. For example, by coupling and extending the cross-stack structure between the device stacks, the device stacks—and the assembly overall—can better withstand impacts or other forces.

At least one embodiment of present technology can comprise an assembly substrate including an upper surface, a first and second die stack at the upper surface, and a cross-stack substrate spaced from the upper surface. The first and second die stacks can each include multiple semiconductor dies in electric communication with the assembly substrate, and the cross-stack substrate can be coupled to and extending between a first and second semiconductor die of the first and second die stacks, respectively. A passive semiconductor component can be carried by the cross-stack substrate, and can be in electric communication with the assembly substrate. Further, the passive semiconductor component can be in electric communication with the first semiconductor die of the first die stack exclusively via the assembly substrate.

In at least one other embodiment of present technology, the assembly can comprise an assembly substrate including an upper surface, a first and second die stack at the upper surface, and a cross-stack substrate spaced from the upper surface and including a top and bottom surface. The first and second die stacks can each include multiple semiconductor dies, and the cross-stack substrate can be coupled to and extending between a first and a second semiconductor die of the first and second die stacks, respectively. A top passive semiconductor component can be carried by the top surface of the cross-stack substrate, and a bottom passive semiconductor component can be carried by the bottom surface of the cross-stack substrate.

At least the above identified embodiments of present technology can be manufactured by providing an assembly substrate having an upper surface, forming a first lower semiconductor die sub-stack at the upper surface and including a first semiconductor die with a top surface, and forming a second lower semiconductor die sub-stack at the upper surface and including a second semiconductor die with a top surface. Next, a cross-stack substrate carrying a passive semiconductor component can be coupled to the top surfaces of the first and second semiconductor dies. A first upper semiconductor die sub-stack can be formed at an upper surface of the cross-stack substrate, including a third semiconductor die, at least a portion of which is vertically aligned with the first lower semiconductor die sub-stack; and a second upper semiconductor die sub-stack can be formed at the upper surface of the cross-stack substrate, including a fourth semiconductor die, at least a portion of which is vertically aligned with the second lower semiconductor die sub-stack.

For case of reference, the semiconductor device and other components are sometimes described herein with reference to top, bottom, left, right, lateral, vertical, uppermost, lowermost, or other similar directional terms relative to the spatial orientation of the embodiments described and/or shown in the figures. The semiconductor devices described herein and modifications thereof can be moved to and/or used in different spatial orientations without changing the structure and/or function of the disclosed embodiments of the present technology.

From the foregoing, it will be appreciated that specific embodiments of the technology have been described herein for purposes of illustration, but well-known structures and functions have not been shown or described in detail to avoid unnecessarily obscuring the description of the embodiments of the technology. To the extent any material incorporated herein by reference conflicts with the present disclosure, the present disclosure controls. Where the context permits, singular or plural terms may also include the plural or singular term, respectively. The terms “comprising,” “including,” “having,” and “with” are used throughout to mean including at least the recited feature(s) such that any greater number of the same features and/or additional types of other features are not precluded. Similarly, use of the word “some” is defined to mean “at least one” of the relevant features and/or elements.

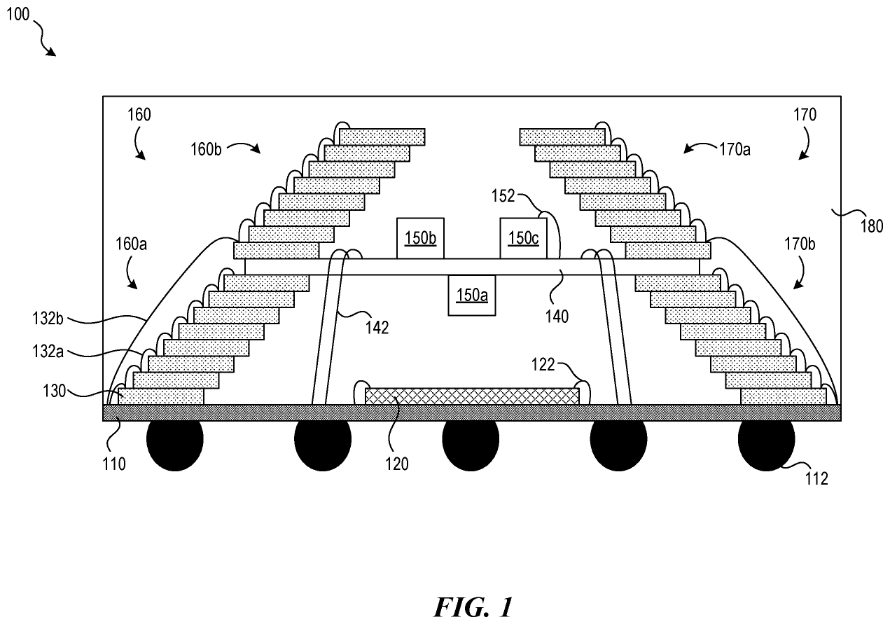

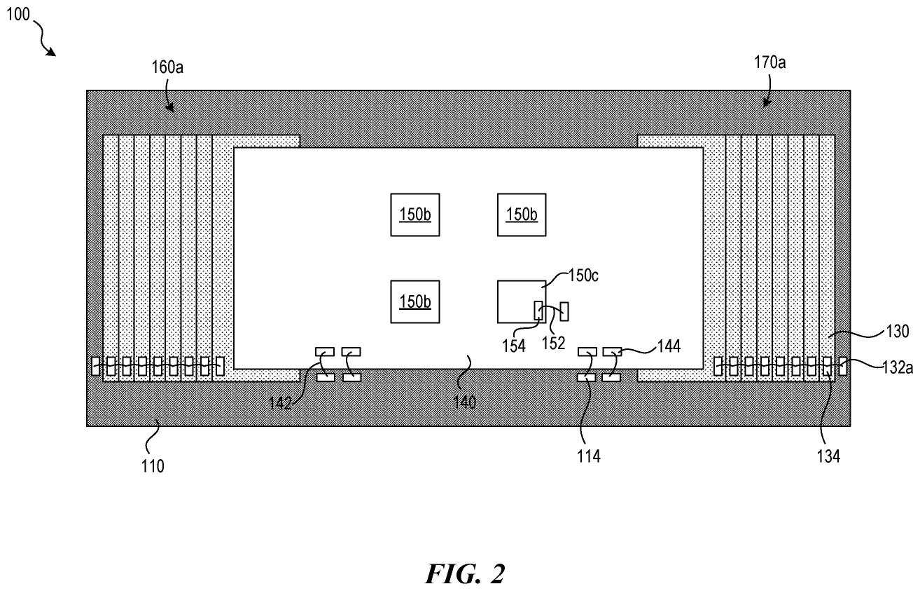

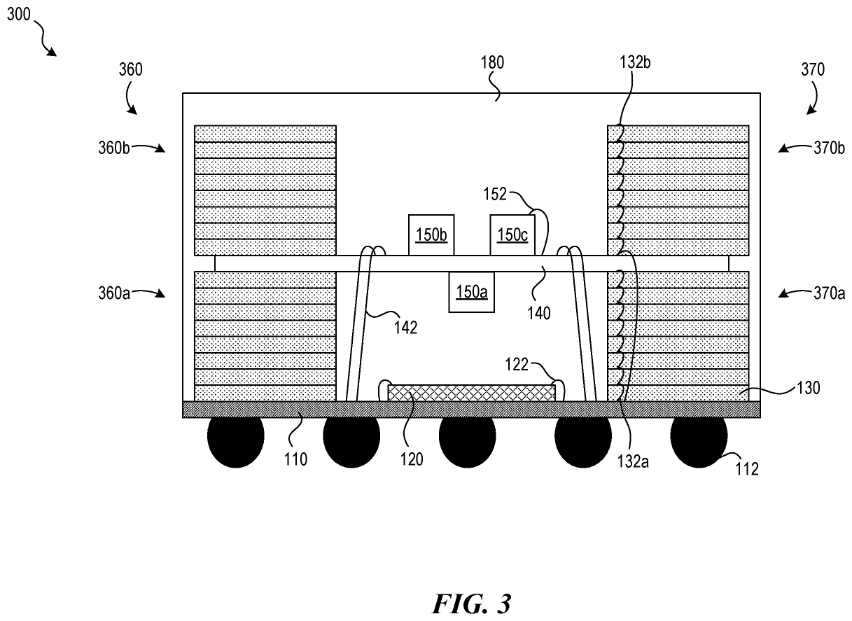

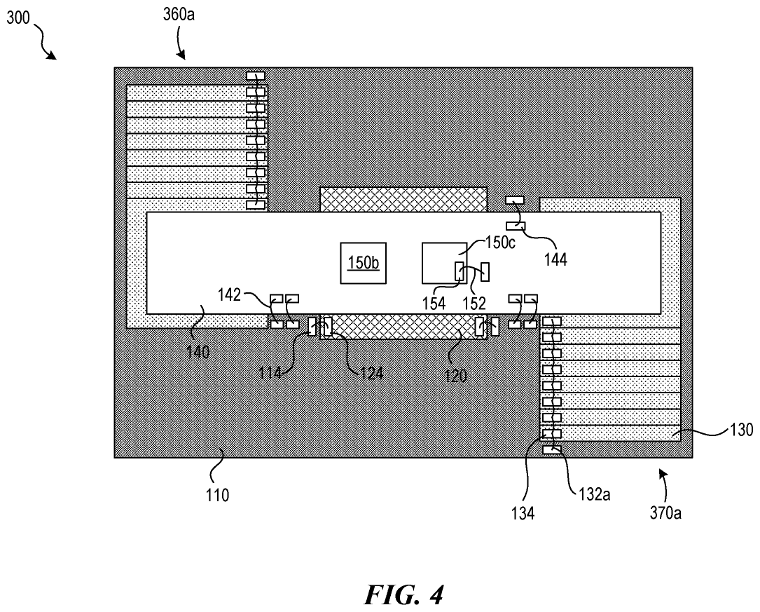

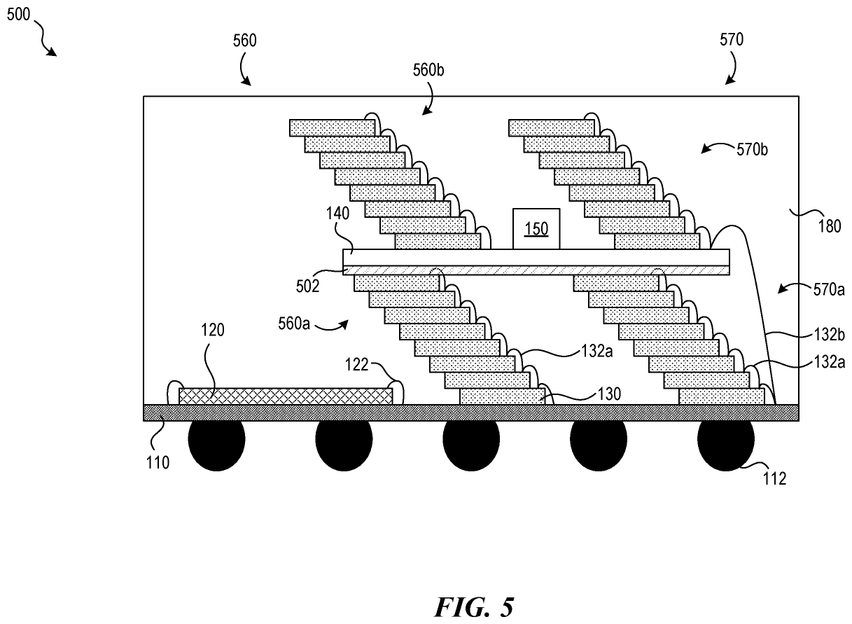

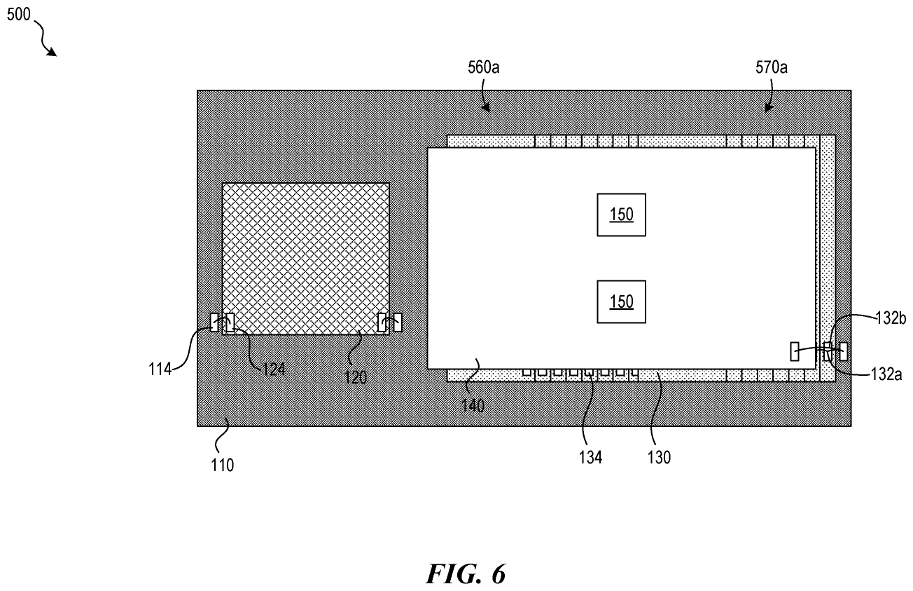

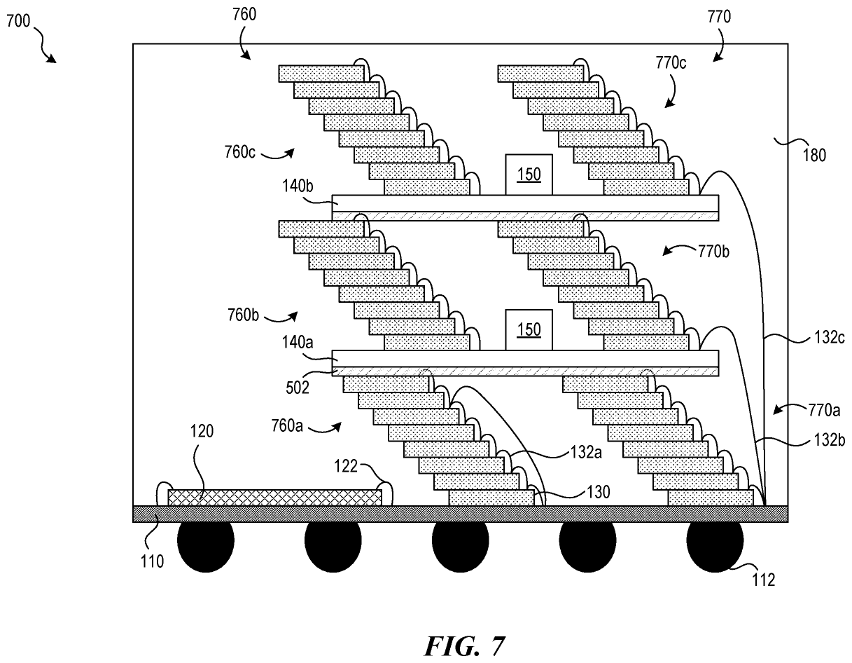

FIGS. 1 and 2 illustrate a semiconductor device assembly 100 with a cross-stack structure 140 extending between a first semiconductor device stack 160 and a second semiconductor device stack 170, configured in accordance with some embodiments of the present technology. Specifically, FIG. 1 is a side view of the assembly 100, and FIG. 2 is a cross-sectional top view of the assembly 100 at a top surface (e.g., an upper surface) of the cross-stack structure 140. The assembly 100 can be a first example of a semiconductor device assembly including a cross-stack structure. However, some or all aspects of the assembly 100, and the elements and/or benefits thereof, can correspond with other examples of semiconductor device assemblies including a cross-stack structure (e.g., the assembly 300 of FIGS. 3 and 4, infra, the assembly 500 of FIGS. 5 and 6, infra, the assembly 700 of FIG. 7, infra, etc.).

Referencing FIGS. 1 and 2, the assembly 100 can include a semiconductor assembly substrate 110 with (i) a controller 120, the first device stack 160 (e.g., semiconductor die stack), and the second device stack 170 coupled to a top surface thereof; and (ii) solder balls 112 coupled a bottom surface (e.g., a lower surface) thereof. Each of the first and second device stacks 160, 170 can include at least one semiconductor device 130 (e.g., a semiconductor die) in a lower device sub-stack 160a, 170a (e.g., a lower or bottom sub-stack, stack portion, or stack section, etc.), and can include at least one device 130 in an upper device sub-stack 160b, 170b (e.g., an upper or top sub-stack, stack portion, or stack section, etc.).

The cross-stack structure 140 can extend between the first and second device stacks 160, 170, distanced from the substrate 110 and/or the controller 120. Further, the cross-stack structure 140 can carry one or more active and/or passive semiconductor components 150 on a top and/or a bottom surface thereof. A plurality of interconnections (e.g., via wires bond, device traces, and/or bond pads) can interconnect the substrate 110, the controller 120, the devices 130, the cross-stack structure 140, and/or the components 150, facilitating electric communication between these elements and operation of the assembly 100. A mold material 180 can cover and/or encase the substrate 110, the controller 120, the device stacks 160, 170 (and the devices 130), the cross-stack structure 140, the components 150, and any other features of the assembly 100, protecting these elements from debris and other external impurities.

Aspects of including cross-stack structures carrying passive and/or active components in semiconductor assemblies (e.g., the cross-stack structure 140 of the assembly 100 carrying the components 150) can provide many benefits over traditional semiconductor device assemblies. For example, by carrying components on cross-stack structures that would otherwise be carried by a substrate, space on the substrate can be opened for new active and/or passive components. Further. routing efficiency can be improved within the assembly substrate. These benefits can increase assembly operating capacity, speed, and signaling integrity, among providing other improvements. Additionally or alternatively, the newly-opened space can be eliminated to reduce the footprint of the substrate. And additionally, the cross-stack structures can increase structural integrity of the assembly by provided an additional rigid element between the device stacks.

The substrate 110 can be a package-level substrate upon which other semiconductor devices are carried (e.g., coupled to, bonded to, attached to, adhered to, etc.). For example, the substrate 110 can be a printed circuit board (PCB), an interposer, or another semiconductor device having functional features therein. The substrate 110 can include the upper surface and the lower surface opposite the upper surface. Substrate bond pads 114 can be at the upper and/or lower surface and in electric communication with one or more functional features within the substrate 110. Traces can extend between two or more of the substrate bond pads 114 and/or one or more of the functional features within the substrate 110. The solder balls 112 can be coupled to the substrate bond pads 114 at the lower surface. The substrate bond pads 114, the traces, and the solder balls 112 can allow communication (e.g., electric communication, interconnection) between the functional features of the substrate 110—or the substrate 110, generally—and elements external thereto.

The controller 120 and/or each of the devices 130 can be a memory and/or processing device, such as a memory die (e.g., a NAND die, a DRAM die, a NOR die, a PCM die, a FeRAM die, etc.), a graphics processing unit, a logic device, an interposer, a PCB, or any similar semiconductor device with functional features configured to facilitate operation of the assembly 100. The controller 120 and/or each of the devices 130 can include an upper surface and a lower surface opposite the upper surface. Controller bond pads 124 (visually obstructed in FIG. 2 by the cross-stack structure 140, but visible in FIG. 4) and device bond pads 134 can be at the upper and/or lower surface of the controller 120 and the devices 130, respectively. Further, traces can extend between two or more controller bond pads 124 or device bond pads 134, respectively. The controller bond pads 124 and traces, and the device bond pads 134 and traces can be in communication (e.g., electric communication, interconnection) with one or more functional features within the controller 120 and the devices 130, respectively. Via these interconnections, the controller 120 and/or the devices 130 can communication between their respective functional features—or the controller 120 and the devices 130, generally—and elements external thereto. In some embodiments, the assembly 100 can exclude the controller.

The cross-stack structure 140 can be a passive or an active component of the assembly 100. For example, the cross-stack structure 140 can be a routing component (e.g., substrate, interposer, etc.), similar to the assembly substrate 110; or the cross-stack structure 140 can be a memory and/or processing component, similar to the controller 120 or the devices 130. In some embodiments, and as illustrated in FIGS. 1 and 2, the cross-stack structure 140 can be an interposer with an upper surface and a lower surface opposite the upper surface, and including a semiconductor substrate material. Further, the cross-stack structure 140 can have a major dimension (e.g., a first dimension, a length), and a minor dimension (e.g., a second dimension, a width) perpendicular to, and less than, the major dimension. Cross-stack structure bond pads 144 can be at the upper and/or lower surface of the cross-stack structure 140. Two or more of the cross-stack structure bond pads 144 can be interconnected by traces within the cross-stack structure 140 and extending therebetween.

The cross-stack structure 140 can carry the one or more passive and/or active semiconductor components 150 on the upper and/or lower surface thereof. The components 150 carried by the cross-stack structure 140 can supplement and/or replace similar components of the assembly 100 (e.g., on the substrate 110). For example, the cross-stack structure 140 can carry the components 150 (i) direct-bonded to the lower surface (e.g., lower components 150a), (ii) direct-bonded to the upper surface (e.g., direct bonded upper components 150b), and/or (iii) wire-bonded to the upper surface (e.g., wire-bonded components 150c). Each of the components 150 can be a capacitor, resistor, inductor, ferrite bead, transistor, transducer, amplifier, basic logic gate or plurality of logic gates, sensor, antenna, piezoelectric device, terminal, connector, or any similar passive component supporting operation of the assembly 100. In some embodiments, one or more of the components 150 can be a memory and/or processing device (e.g., the devices 130), or any similar active component of the assembly 100. Further, the wire-bonded components 150c can include one or more component bond pads 154 on a surface thereof.

One or more of the substrate bond pads 114, the controller bond pads 124, the device bond pads 134, the cross-stack structure bond pads 144, and/or the component bond pads 154 can include a corresponding bond pad on another element of the assembly 100. For example, the substrate 110 can include one or more of the substrate bond pads 114 corresponding with and laterally (and, in some embodiments, vertically) adjacent to (i) the controller bond pads 124, (ii) one or more of the device bond pads 134, (iii) the cross-stack structure bond pads 144, and/or (iv) the component bond pads 154. Further, the cross-stack structure 140 can include one or more of the cross-stack structure bond pads 144 corresponding with and laterally adjacent to the component bond pads 154.

Wire bonds can extend between corresponding bond pads of the assembly 100 to facilitate electric communication between the interconnected elements. For example, regarding each pair of corresponding bond pads, respectively: (i) a wire bond 122 can extend between the substrate bond pads 114 and the controller bond pads 124; (ii) a wire bond 132a can extend between the substrate bond pads 114 and one or more of the device bond pads 134 of the first and second lower device sub-stacks 160a, 170a, respectively; (iii) a wire bond 132b can extend between the substrate bond pads 114 and one or more of the device bond pads 134 of the first and second upper device sub-stacks 160b, 170b, respectively; (iv) a wire bond 142 can extend between the substrate bond pads 114 and the cross-stack structure bond pads 144; and (v) a wire bond 152 can extend between the cross-stack structure bond pads 144 and the component bond pads 154. In some embodiments, a wire bond can additionally or alternatively extend between the substrate bond pads 114 and the component bond pads 154.

The bond pads, the wire bonds, and the traces of the assembly 100 can each include any suitable conductive material such as, for example, copper, gold, silver, aluminum, tungsten, cobalt, nickel, or any other suitable conductive material, or a combination thereof. For case of illustration and reference, a single or selected bond pads and wire bonds are shown for the elements of the assembly 100 in FIGS. 1 and 2 (and for the assembly 300 in FIGS. 3 and 4, infra, the assembly 500 of FIGS. 5 and 6, infra, and the assembly 700 of FIG. 7). It is understood, however, that the assembly 100, or the elements thereof, can include one or more additional bond pads and corresponding wire bonds. For example, one or more of the elements of the assembly 100 can each include 5, 10, 50, 100, or 1000 bond pads, in total, or any specific number greater-than or therebetween. Further, one or more of the elements of the assembly 100 can include additional wire bonds extending between the additional bond pads.

Referencing FIG. 1, the first and second device stacks 160, 170 can each include the respective first and second lower device sub-stack 160a, 170a carried by (e.g., coupled to, bonded to, attached to, adhered to, etc.) the substrate 110. The first and second lower device sub-stacks 160a, 170a can each include a lowermost device 130 (e.g., bottom device, first device, etc.) carried by the substrate 110, laterally spaced from the controller 120, and opposite the controller 120 from the lowermost device 130 of the opposing lower device sub-stack 160a, 170a. One or more of the devices 130 (e.g., intermediary devices, middle devices, etc.) can be carried by the lowermost device 130. An uppermost device 130 (e.g., top device, last device, etc.) can be carried by the last intermediary device 130. Each of the intermediary devices 130 and the uppermost devices 130 can be shingled relative to the preceding device 130, exposing the device bond pads 134 thereon. As illustrated, the first and second lower device sub-stacks 160a, 170a can each include eight of the devices 130. In some embodiments, the first and second lower device sub-stacks 160a, 170a can each include fewer (e.g., 1, 2, 3, 4, 5, 6, or 7) or additional (e.g., 16, 24, etc.), or any specific number therebetween or greater than, devices 130.

The cross-stack structure 140 (i) can extend between the first and second device stacks 160, 170, distanced from the substrate 110 and the controller 120; (ii) can be carried by the uppermost devices 130 of the first and second lower device sub-stacks 160a, 170a; and (iii) can at least partially (or fully) cover the controller 120 from above. A first and second end (e.g., side) of the cross-stack structure 140 perpendicular to the major dimension thereof can be offset (e.g., shingled) relative to the uppermost devices 130 of the first and second lower device sub-stacks 160a, 170a, exposing the device bond pads 134 thereof. In some embodiments, the first and second ends of the cross-stack structure 140 can extend to (or past) the uppermost devices 130. In these embodiments, the cross-stack structure 140 can be coupled to the uppermost devices 130 with a film-over-wire (FOW) and interconnections with the device bond pads 134 can be made through the FOW.

As illustrated in FIG. 2, the cross-stack structure 140 can also be offset relative to the uppermost devices 130 at a first and second side of the cross-stack structure 140 parallel with the major dimension thereof. That is, the minor dimension of the cross-stack structure 140 (e.g., the width) can be less than the corresponding dimension (e.g., the width) of the devices 130. Further, one or both of the first and second sides of the cross-stack structure 140 can be offset from the corresponding sides of the devices 130.

In some embodiments, the minor dimension of the cross-stack structure 140 can be the same as, or greater than, the corresponding dimension of the devices 130. In these embodiments, one or both sides of the cross-stack structure 140 can align with, or be over, the sides of the devices 130. By including the first and second sides of the cross-stack structure 140 as offset from the sides of the devices 130 (e.g., when the minor dimension is less than the corresponding dimension of the devices 130), the cross-stack structure 140 can be more narrow and therefore more manipulable during manufacturing of the assembly 100. Further, the narrow cross-stack structure 140 can provide additional space for equipment interfacing with the substrate 110 (e.g., for wire bond formation) and reduce net assembly materials. By including the first and/or second sides of the cross-stack structure 140 as over the sides of the devices 130 (e.g., when the minor dimension is equal to or greater than the corresponding dimension of the devices 130), the cross-stack structure 140 can include additional surface area for placing the components 150 thereon, further increasing the amount of newly opened space on the substrate 110.

The upper device sub-stacks 160b, 170b can each include a lowermost device 130 carried by the cross-stack structure 140. The lowermost devices 130 of the upper device sub-stacks 160b, 170b can align with, or can be over or offset from (along the major dimension), the first and second ends of the cross-stack structure 140, respectively. For example, as illustrated in FIG. 1, the lowermost devices 130 are over the first and second ends of the cross-stack structure 140. One or more devices 130 (e.g., intermediary devices, middle devices, etc.) can be carried by the lowermost device 130. An uppermost device 130 can be carried by the last intermediary device 130. Each of the intermediary devices 130 and the uppermost devices 130 can be shingled relative to the preceding device 130, exposing the device bond pads 134 thereon. As illustrated, the upper device sub-stacks 160b, 170b can each include eight of the devices 130 (e.g., 32 total devices 130 in the assembly 100). In some embodiments, the upper device sub-stacks 160b, 170b can each instead include fewer (e.g., 1, 2, 3, 4, 5, 6, or 7) or additional (e.g., 16, 24, etc.), or any specific number therebetween or greater than, devices 130.

The devices 130 and/or the cross-stack structure 140 can be carried by the substrate 110, the devices 130, or the cross-stack structure 140, respectively, by coupling the device 130 or the cross-stack structure 140 to the proceeding element of the assembly 100. For example, these elements can be coupled using any suitable method, such as solder bonding, hybrid bonding, surface bonding, adhesive bonding (e.g., die attach film (DAF), FOW, etc.), or any similar, suitable coupling method. The devices 130 of the first and second device stacks 160, 170 can be shingled relative to the preceding devices 130 along a horizontal centerline of the substrate 110 and/or over the controller 120 (e.g., toward a center of the assembly 100). That is, in some embodiments, the angle of the first and second device stacks 160, 170 can be facing and aligned with one another. In these embodiments, the devices 130 can be shingled toward the center, thereby exposing the device bond pads 134 on a portion of the devices 130 opposite from the cross-stack structure 140, and parallel with the first and second end of the cross-stack structure 140. Further, in this arrangement, at least a portion (or all) of one or more of the devices 130 can be above the controller 120.

In some embodiments, shingling the devices 130 toward the center can align the shingled devices 130—and the device stacks 160, 170—with the major dimension of the cross-stack structure 140. By shingling the devices 130 toward the center of the assembly 100, the controller 120, the devices 130, the cross-stack structure 140, and the components 150 can be consolidated along the horizontal centerline of the assembly 100. The assembly 100 can therefore at least have a reduced width, and the assembly 100 can therefore be better suited for certain applications of the present technology requiring narrow semiconductor device assemblies.

The controller 120, the devices 130, and the components 150 can communicate (e.g., can be interconnected) via the wire bonds and the bond pads of the assembly 100, and the traces within the substrate 110 and the cross-stack structure 140. For example, the controller 120 and/or the devices 130 can exclusively communicate with the components 150 via the respective wire bond 122, 132a, 132b, 142, 152 and the traces within the substrate 110 and the cross-stack structure 140. That is, in some embodiments, no wire bonds—or direct interconnections, generally—may extend from (e.g., between) the controller 120 and/or the devices 130 to the cross-stack structure 140 and/or the components 150. In these embodiments, the cross-stack structure 140 can act as a passive, routing structure transmitting signals from elements of the assembly 100 to the components 150.

By limiting interconnections between the controller 120 and the devices 130 with the components 150 to exclusively through the substrate 110 and the cross-stack structure 140, the traces within the substrate 110 can be organized to maximize routing efficiency. For example, the traces can be aligned along certain portions of the substrate 110 and/or the cross-stack structure 140, as opposed to weaving around other traces or components on the substrate 110. Further, the number of wire bonds needed between the controller 120 and/or the devices 130 and other elements of the assembly 100 can be reduced.

FIGS. 3 and 4 illustrate a semiconductor device assembly 300 with the cross-stack structure 140 extending between a first semiconductor device stack 360 and a second semiconductor device stack 370, configured in accordance with some embodiments of the present technology. Specifically, FIG. 3 is a side view of the assembly 300, and FIG. 4 is a cross-sectional top view of the assembly 300 at the top surface of the cross-stack structure 140. The assembly 300 can be a second example of a semiconductor device assembly including a cross-stack structure. However, some or all aspects of the assembly 300, and the elements and/or benefits thereof, can correspond with other examples of semiconductor device assemblies including a cross-stack structure (e.g., the assembly 100 of FIGS. 1 and 2, the assembly 500 of FIGS. 5 and 5, infra, the assembly 700 of FIG. 7, infra, etc.).

Referencing FIGS. 3 and 4, the assembly 300 can include generally the same elements, arrangements therebetween (e.g., configurations, interconnections), and benefits thereof, and other features as the assembly 100 of FIGS. 1 and 2. However, the assembly 300 of FIGS. 3 and 4 can instead include device stacks (e.g., the first and second device stacks 360, 370) in an alternative orientation from the first and second device stacks 160, 170 of FIGS. 1 and 2. As illustrated in FIGS. 3 and 4, the first and second device stacks 360, 370 can instead be oriented with the devices 130 therein shingled parallel to a vertical centerline of the substrate 110 and misaligned with one another (e.g., the first and second device stacks 360, 370 can be shingled along a first direction, and separated from one another a first distance perpendicular to the first direction).

The first and second device stacks 360, 370 can each include the respective first and second lower device sub-stack 360a, 370a carried by the substrate 110. The first and second lower device sub-stacks 360a, 370a can each include a lowermost device 130 carried by the substrate 110, laterally spaced from the controller 120, and opposite the controller 120 from the lowermost device 130 of the opposing lower device sub-stack 360a, 370a. One or more devices 130 (e.g., intermediary devices, middle devices, etc.) can be carried by the lowermost device 130. An uppermost device 130 can be carried by the last intermediary device 130. Each of the intermediary devices 130 and the uppermost devices 130 can be shingled relative to the preceding device 130, exposing the device bond pads 134 thereon. As illustrated, the lower device sub-stacks 360a, 370a can each include eight of the devices 130. In some embodiments, the lower device sub-stacks 360a, 370a can each instead include fewer (e.g., 1, 2, 3, 4, 5, 6, or 7) or additional (e.g., 16, 24, etc.), or any specific number therebetween or greater than, devices 130.

The cross-stack structure 140 (i) can extend between the first and second device stacks 360, 370, distanced from the substrate 110 and the controller 120; (ii) can be carried by the uppermost devices 130 of the first and second lower device sub-stacks 360a, 370a, and (iii) can at least partially (or fully) cover the controller 120 from above. As illustrated in FIG. 4, the first and second side of the cross-stack structure 140 (e.g., sides parallel to the major dimension) can be offset relative to the sides uppermost devices 130, exposing the device bond pads 134 thereof. The cross-stack structure 140 can also be offset relative to the uppermost devices 130 at the first and second ends of the cross-stack structure 140 (e.g., sides parallel to the minor dimension). That is, the major dimension of the cross-stack structure 140 (e.g., the length) can be less than a distance from the exterior side (e.g., a left side as shown) of the top device 130 of the first lower device sub-stack 360a to the exterior side (e.g., a right side as shown) of the top device 130 of the second lower device sub-stack 370a (the “device stacks exterior width”).

In these arrangements, one or both ends of the cross-stack structure 140 can be offset from the furthest left and right sides of the devices 130. In some embodiments, the major dimension of the cross-stack structure 140 can instead be the same as, or greater than, the device stacks exterior width. In these embodiments, one or both ends of the cross-stack structure 140 can align with, or be over, the furthest left and right sides of the devices 130. By including the first and second ends of the cross-stack structure 140 as offset from the furthest left and right sides of the devices 130 (e.g., when the major dimension is less than the device stacks exterior width), the cross-stack structure 140 can be shorter and therefore be more manipulable during manufacturing of the assembly 300, and can reduce net assembly materials requirements. By including the first and/or second ends of the cross-stack structure 140 as over the furthest left and/or right sides of the devices 130 (e.g., when the major dimension is equal to or greater than the device stacks exterior width), the cross-stack structure 140 can include additional surface area opposite the first or the second device stack 360, 370, thereby providing additional surface area to placing the components 150 thereon, further increasing the amount of newly opened space on the substrate 110.

The upper device sub-stacks 360b, 370b can each include a lowermost device 130 carried by the cross-stack structure 140. The lowermost devices 130 of the upper device sub-stacks 360b, 370b can align with, or can be over or offset from (along the major or the minor dimension), the first and second ends, and/or the first and second sides of the cross-stack structure 140, respectively. For example, as illustrated in FIG. 3, the lowermost devices 130 are over the first and second ends of the cross-stack structure 140. One or more devices 130 (e.g., intermediary devices, middle devices, etc.) can be carried by the lowermost device 130. An uppermost device 130 can be carried by the last intermediary device 130. Each of the intermediary devices 130 and the uppermost devices 130 can be shingled relative to the preceding device 130, exposing the device bond pads 134 thereon. As illustrated in FIG. 3, the upper device sub-stacks 360b, 370b can each include eight of the devices 130 (e.g., 32 total devices 130 in the assembly 300). In some embodiments, the upper device sub-stacks 360b, 370b can each instead include fewer (e.g., 1, 2, 3, 4, 5, 6, or 7) or additional (e.g., 16, 24, etc.), or any specific number therebetween or greater than, devices 130.

As best shown by the first and second lower device sub-stack 360a, 370a in FIG. 4, the devices 130 of the first and second device stacks 360, 370 can be shingled relative to the preceding devices 130 parallel to, and offset from, a vertical centerline of the substrate 110 and/or alongside the controller 120 (e.g., adjacent to an edge of the assembly 300). That is, in some embodiments, the angle of the first and second device stacks 360, 370 can be facing, and misaligned relative to one another. In these embodiments, the devices 130 can be shingled parallel to, and offset from, the vertical centerline of the substrate 110, thereby exposing the device bond pads 134 on a portion of the devices 130 opposite from the cross-stack structure 140 and parallel with the first and second sides of the cross-stack structure 140.

In some embodiments, shingling the devices 130 parallel to, and offset from, the vertical centerline can align the shingled devices 130—and the device stacks 360, 370—with the minor dimension of the cross-stack structure 140. With the device stacks 360, 370 in this orientation, the substrate 110—and the assembly 300, generally—can more closely resemble a square. The assembly 300 can therefore be more compact and can therefore be better suited for certain application of the present technology requiring a compact semiconductor assembly footprint.

FIGS. 5 and 6 illustrate a semiconductor device assembly 500 with the cross-stack structure 140 extending between a first semiconductor device stack 560 and a second semiconductor device stack 570, configured in accordance with some embodiments of the present technology. Specifically, FIG. 5 is a side view of the assembly 500, and FIG. 6 is a cross-sectional top view of the assembly 500 at the top surface of the cross-stack structure 140. The assembly 500 can be a third example of a semiconductor device assembly including a cross-stack structure. However, some or all aspects of the assembly 500, and the elements and/or benefits thereof, can correspond with other examples of semiconductor device assemblies including a cross-stack structure (e.g., the assembly 100 of FIGS. 1 and 2, the assembly 300 of FIGS. 3 and 4, the assembly 700 of FIG. 7, infra, etc.).

Referencing FIGS. 5 and 6, the assembly 500 can include generally the same elements, arrangements therebetween (e.g., configurations, interconnections), and benefits thereof, and other features as the assembly 100 of FIGS. 1 and 2, and the assembly 300 of FIGS. 3 and 4. However, the assembly 500 of FIGS. 5 and 6 can instead include device stacks (e.g., the first and second device stacks 560, 570) in an alternative orientation from the first and second device stacks 160, 170 of FIGS. 1 and 2, and from the first and second device stacks 360, 370 of FIGS. 3 and 4. As illustrated in FIGS. 5 and 6, the first and second device stacks 560, 570 can instead be oriented with the devices 130 therein shingled parallel to the horizontal centerline of the substrate 110, aligned with one another, and facing the same direction (e.g., the first and second device stacks 560, 570 can be shingled in the same direction).

The first and second device stacks 560, 570 can each include the respective first and second lower device sub-stack 560a, 570a carried by the substrate 110. The first and second lower device sub-stacks 560a, 570a can each include a lowermost device 130 carried by the substrate 110, with the first lower device sub-stack 560a a first distance from the controller 120, and with the second lower device sub-stack 570a a second distance, greater than the first distance, from the controller 120. One or more devices 130 (e.g., intermediary devices, middle devices, etc.) can be carried by the lowermost device 130. An uppermost device 130 can be carried by the last intermediary device 130. Each of the intermediary devices 130 and the uppermost devices 130 can be shingled relative to the preceding device 130, exposing the device bond pads 134 thereon. As illustrated, the lower device sub-stacks 560a, 570a can each include eight of the devices 130. In some embodiments, the lower device sub-stacks 560a, 570a can each instead include fewer (e.g., 1, 2, 3, 4, 5, 6, or 7) or additional (e.g., 16, 24, etc.), or any specific number therebetween or greater than, devices 130.

The cross-stack structure 140 (i) can extend between the first and second device stacks 560, 570, distanced from the substrate 110 and the controller 120; (ii) can be carried by the uppermost devices 130 of the first and second lower device sub-stacks 560a, 570a with a FOW material 502 therebetween, and (iii) can at least partially cover the controller 120 from above. The FOW material 502 can couple the cross-stack structure 140 to the uppermost devices 130, and vertically offset the cross-stack structure 140 from the uppermost devices 130, allowing the wire bonds 132a to couple with the device bond pads 134 thereof. As illustrated in FIGS. 5 and 6, the first and second ends of the cross-stack structure 140 can extend over the uppermost devices 130, exposing the cross-stack structure bond pads 144 for interconnection with the cross-stack structure wire bonds 142. That is, the major dimension of the cross-stack structure 140 (e.g., the length) can be greater than distance from the exterior side (e.g., a left side as shown) of the top device 130 of the first lower device sub-stack 560a to the exterior side (e.g., a right side as shown) of the top device 130 of the second lower device sub-stack 570a (the “lower device stacks exterior width”).

The upper device sub-stacks 560b, 570b can each include a lowermost device 130 carried by the cross-stack structure 140, with the first upper device sub-stack 560b a third distance from the controller 120, and with the second upper device sub-stack 570b a fourth distance, greater than the third distance, from the controller 120. The third distance can be the same as the first distance (e.g., of the first lower device sub-stack 560a), and the fourth distance can be the same as the second distance (e.g., of the second lower device sub-stack 570a). That is, the upper device sub-stacks 560b, 570b can be vertically aligned with the lower device sub-stacks 560a, 570a. In some embodiments, and as illustrated in FIG. 5, the third and fourth distances can be less than the first distance and the second distance, respectively. Further, the third and fourth distances can be greater than the first distance and the second distance.

Referencing FIG. 5, the lowermost devices 130 of the upper device sub-stacks 560b, 570b can be offset from (along the major or the minor dimension) the first and second ends, and/or the first and second sides of the cross-stack structure 140, respectively. For example, as illustrated, the lowermost devices 130 are offset from the first and second ends of the cross-stack structure 140. One or more devices 130 (e.g., intermediary devices, middle devices, etc.) can be carried by the lowermost device 130. An uppermost device 130 can be carried by the last intermediary device 130. Each of the intermediary devices 130 and the uppermost devices 130 can be shingled relative to the preceding device 130, exposing the device bond pads 134 thereon. As illustrated, the upper device sub-stacks 560b, 570b can each include eight of the devices 130 (e.g., 32 total devices 130 in the assembly 500). In some embodiments, the upper device sub-stacks 560b, 570b can each instead include fewer (e.g., 1, 2, 3, 4, 5, 6, or 7) or additional (e.g., 16, 24, etc.), or any specific number therebetween or greater than, devices 130.

The devices 130 of the first and second device stacks 560, 570 can be shingled relative to the preceding devices 130 parallel to the horizontal centerline of the substrate 110 and/or toward the controller 120. That is, in some embodiments, the devices 130 of the first and second device stacks 560, 570 can be shingled in the same direction to expose the device bond pads 134 on a portion of the devices 130 opposite from the controller 120. With the device stacks 560, 570 in this orientation, the controller 120 can be positioned adjacent to an end of the substrate 110 (e.g., as opposed to under and/or between the device stacks).

FIG. 7 is a side view of a semiconductor device assembly 700 with cross-stack structures 140a, 140b extending between a first semiconductor device stack 760 and a second semiconductor device stack 770, configured in accordance with some embodiments of the present technology. The assembly 700 can be a fourth example of a semiconductor device assembly including a cross-stack structure. However, some or all aspects of the assembly 700, and the elements and/or benefits thereof, can correspond with other examples of semiconductor device assemblies including a cross-stack structure (e.g., the assembly 100 of FIGS. 1 and 2, the assembly 300 of FIGS. 3 and 4, the assembly 500 of FIGS. 5 and 6, etc.).

Referencing FIG. 7, the assembly 700 can include generally the same elements, arrangements therebetween (e.g., configurations, interconnections), and benefits thereof, and other features as the assembly 100 of FIGS. 1 and 2, the assembly 300 of FIGS. 3 and 4, and the assembly 500 of FIGS. 5 and 6. However, the assembly 700 of FIG. 7 can instead include device stacks (e.g., the first and second device stacks 760, 770) with multiple cross-stack structures therebetween. Further, as illustrated in FIG. 7, the first and second device stacks 760, 770 can each include additional (e.g., more than two) sub-stacks, such as lower sub-stacks 760a, 770a; middle sub-stacks 760b, 770b; and upper sub-stacks 760c, 770c.

The first and second device stacks 760, 770 can each include (i) the respective first and second lower device sub-stack 760a, 770a carried by the substrate 110, (ii) the respective first and second middle device sub-stack 760b, 770b carried by a first cross-stack structure 140a, and (iii) the respective first and second upper device sub-stack 760c, 770c carried by a second cross-stack structure 140b. The devices 130 within the middle device sub-stacks 760b, 770b can be in electric communication with the substrate 110 via the first cross-stack structure 140a and the wire bonds 132b. The devices 130 within the upper device sub-stack 760c, 770c can be in electric communication with the substrate 110 via the second cross-stack structure 140b and wire bonds 132c.

The first and second lower device sub-stacks 760a, 770a can each include a lowermost device 130 carried by the substrate 110, with the first lower device sub-stack 760a a first distance from the controller 120, and with the second lower device sub-stack 770a a second distance, greater than the first distance, from the controller 120. One or more devices 130 (e.g., intermediary devices, middle devices, etc.) can be carried by the lowermost device 130. An uppermost device 130 can be carried by the last intermediary device 130. Each of the intermediary devices 130 and the uppermost devices 130 can be shingled relative to the preceding device 130, exposing the device bond pads 134 thereon. As illustrated, the lower device sub-stacks 760a, 770a can each include eight of the devices 130. In some embodiments, the lower device sub-stacks 760a, 770a can each instead include fewer (e.g., 1, 2, 3, 4, 5, 6, or 7) or additional (e.g., 16, 24, etc.), or any specific number therebetween or greater than, devices 130.

The first cross-stack structure 140a (i) can extend between the first and second device stacks 760, 770, distanced from the substrate 110 and the controller 120; (ii) can be carried by the uppermost devices 130 of the first and second lower device sub-stacks 760a, 770a with a FOW material 502 therebetween, and (iii) can at least partially cover the controller 120 from above. The FOW material 502 can couple the first cross-stack structure 140a to the uppermost devices 130, and vertically offset the first cross-stack structure 140a from the uppermost devices 130, allowing the wire bonds 132a to couple with the device bond pads 134 thereof. As illustrated in FIG. 7, the first and second ends of the first cross-stack structure 140a can extend over the uppermost devices 130, exposing the cross-stack structure bond pads 144 for interconnection with the cross-stack structure wire bonds 142. That is, the major dimension of the first cross-stack structure 140a (e.g., the length) can be greater than distance from the exterior side of the top device 130 of the first lower device sub-stack 760a to the exterior side of the top device 130 of the second lower device sub-stack 770a (the “lower device stacks exterior width”).

The middle device sub-stacks 760b, 770b can each include a lowermost device 130 carried by the first cross-stack structure 140a, with the first middle device sub-stack 770b a third distance from the controller 120, and with the second middle device sub-stack 770b a fourth distance, greater than the third distance, from the controller 120. The third distance can be the same as the first distance, and the fourth distance can be the same as the second distance. That is, the middle device sub-stacks 760b, 770b can be vertically aligned with the lower device sub-stacks 760a, 770a. In some embodiments, and as illustrated in FIG. 7, the third and fourth distances can be less than the first distance and the second distance, respectively. Further, the third and fourth distances can be greater than the first distance and the second distance.

Referencing FIG. 7, the lowermost devices 130 of the middle device sub-stacks 760b, 770b can be offset from (along the major or the minor dimension) the first and second ends, and/or the first and second sides of the first cross-stack structure 140a, respectively. For example, as illustrated, the lowermost devices 130 are offset from the first and second ends of the first cross-stack structure 140a. One or more devices 130 (e.g., intermediary devices, middle devices, etc.) can be carried by the lowermost device 130. An uppermost device 130 can be carried by the last intermediary device 130. Each of the intermediary devices 130 and the uppermost devices 130 can be shingled relative to the preceding device 130, exposing the device bond pads 134 thereon. As illustrated, the middle device sub-stacks 760b, 770b can each include eight of the devices 130. In some embodiments, the middle device sub-stacks 760b, 770b can each instead include fewer (e.g., 1, 2, 3, 4, 5, 6, or 7) or additional (e.g., 16, 24, etc.), or any specific number therebetween or greater than, devices 130.

The second cross-stack structure 140b (i) can extend between the first and second device stacks 760, 770, distanced from the substrate 110, the controller 120, and the first cross-stack structure 140a; (ii) can be carried by the uppermost devices 130 of the first and second middle device sub-stacks 760b, 770b with a FOW material 502 therebetween, and (iii) can at least partially cover the controller 120 from above. As illustrated in FIG. 7, the first and second ends of the second cross-stack structure 140b can extend over the uppermost devices 130, exposing the cross-stack structure bond pads 144 for interconnection with the cross-stack structure wire bonds 142. That is, the major dimension of the second cross-stack structure 140b can be greater than distance from the exterior side of the top device 130 of the first middle device sub-stack 760b to the exterior side of the top device 130 of the second middle device sub-stack 770b (the “middle device stacks exterior width”).

The upper device sub-stacks 760c, 770c can each include a lowermost device 130 carried by the second cross-stack structure 140b, with the first upper device sub-stack 760c a fifth distance from the controller 120, and with the second upper device sub-stack 770c a sixth distance, greater than the fifth distance, from the controller 120. The fifth distance can be the same as the first distance (e.g., of the first lower device sub-stack 760a) and/or the third distance (e.g., of the first middle device sub-stack 760b). The sixth distance can be the same as the second distance (e.g., of the second lower device sub-stack 770a) and/or the fourth distance (e.g., of the second middle device sub-stack 770b). That is, the upper device sub-stacks 760c, 770c can be vertically aligned with the lower device sub-stacks 760a, 770a and/or the middle device sub-stacks 760b, 770b. In some embodiments, and as illustrated in FIG. 7, the fifth and sixth distances can be less than the first distance and the second distance, and equal to the third and fourth distances, respectively. Further, the fifth and sixth distances can be greater than the first distance and the second distance, and/or the third distance and the fourth distance, respectively.

Referencing FIG. 7, the lowermost devices 130 of the upper device sub-stacks 760c, 770c can be offset from (along the major or the minor dimension) the first and second ends, and/or the first and second sides of the second cross-stack structure 140b, respectively. For example, as illustrated, the lowermost devices 130 are offset from the first and second ends of the second cross-stack structure 140b. One or more devices 130 (e.g., intermediary devices, middle devices, etc.) can be carried by the lowermost device 130. An uppermost device 130 can be carried by the last intermediary device 130. Each of the intermediary devices 130 and the uppermost devices 130 can be shingled relative to the preceding device 130, exposing the device bond pads 134 thereon. As illustrated, the upper device sub-stacks 760c, 770c can each include eight of the devices 130 (e.g., 48 total devices 130 in the assembly 700). In some embodiments, the upper device sub-stacks 760c, 770c can each instead include fewer (e.g., 1, 2, 3, 4, 5, 6, or 7) or additional (e.g., 16, 24, etc.), or any specific number therebetween or greater than, devices 130.

The devices 130 of the first and second device stacks 760, 770 can be shingled relative to the preceding devices 130 parallel to the horizontal centerline of the substrate 110 and/or toward the controller 120. That is, in some embodiments, the devices 130 of the first and second device stacks 760, 770 can be shingled in the same direction to expose the device bond pads 134 on a portion of the devices 130 opposite from the controller 120. With the device stacks 760, 770 in this orientation, the controller 120 can be positioned adjacent to an end of the substrate 110 (e.g., as opposed to under and/or between the device stacks).

Multiple additional embodiments and examples of the preset technology exist. A non-exhaustive selection of examples are described in the following paragraphs. Elements from the assembly 100 of FIGS. 1 and 2 (e.g., example one), the assembly 300 of FIGS. 3 and 4 (e.g., example two), the assembly 500 of FIGS. 5 and 6 (e.g., example three), and the assembly 700 (e.g., example four) are referenced in these examples for illustrative purposes only. The following four examples can, but do not always, include the same and/or similar elements, arrangements, and benefits of the assemblies 100, 300, 500, and 700 of FIGS. 1-7.

A fifth example of a semiconductor device assembly including a cross-stack structure can be generally similar to the preceding and subsequent examples, but can include a first and second device stack in corresponding orientations relative to one another. In the first and second examples, the first device stack 160, 360 faces the second device stack 170, 370. That is, the devices 130 of the first and second device stacks 160, 360, 170, 370 are shingled toward one another. In the fifth example, the devices of the first and second device stacks can instead be shingled in the same direction, like the devices 130 of the device stacks 560, 570 of the third example, but with a controller therebetween. For example, if implemented in the assembly 100 as shown in FIG. 2, all the devices 130 can be shingled from the left to the right (or right to left); and if implemented in the assembly 300 as shown in FIG. 4, all the devices 130 can be shingled from the bottom to the top (or top to bottom). Assemblies corresponding with fifth example can benefit from the ability to rearranging components on the substrate 110 for at least improving routing efficiency.

A sixth example of a semiconductor device assembly including a cross-stack structure can be generally similar to preceding and subsequent examples, but can include one or more additional device stacks carrying the cross stack structure. In the first, second, and third examples, the assemblies 100, 300, 500 each included the cross-stack structure 140 extending between the first and second device stacks 160, 170, 360, 370, 560, 570 respectively. In the sixth example, the assembly can further include the cross-stack structure extending between one or more additional device stacks.

For example, the assembly can include one or more additional device stacks coupled to an assembly substrate (e.g., a third, a fourth, and/or a fifth device stack, etc.). The additional device stacks can each include a lower and an upper device sub-stack. The cross-stack structure can be extended along its major dimension and can be coupled to the additional device stacks. That is, the extended cross-stack structure can be further supported by the lower device sub-stacks of the additional device stacks. Alternatively, the major dimension of the cross-stack structure can be the same, and the device stacks can be condensed along the major dimension. Assemblies corresponding with fourth example can benefit from increased processing capacity and/or operating speed provided by the devices within the additional device stacks. Further, these assemblies can benefit from additional surface area on the cross-stack structure for carrying the components 150 thereon, opening additional space on the assembly substrate.

The angle of the additional device stacks can face the same direction as one of the first and second device stacks, or one or more of the additional device stacks can continue a pattern of the existing device stacks. For example, if the first and second device stacks are facing and aligned with one another (e.g., FIGS. 1 and 2), or are facing and misaligned with one another (e.g., FIGS. 3 and 4), the additional device stacks can repeat, or alternate this pattern. That is, referencing FIG. 2, the first device stack 160 can be shingled from left to right; the second device stack 170 can be shingled from right to left; a third device stack can be shingled from left to right; and a fourth device stack can be shingled from right to left, etc. Similarly, referencing FIG. 4, the first device stack 360 can be shingled from top to bottom; the second device stack 370 can be shingled from bottom to top; a third device stack can be shingled from bottom to top; and a fourth device stack can be shingled from top to bottom, etc. In some embodiments, the angles of the additional device stacks can correspond with the angles of the device stacks of both FIGS. 2 and 4. These alternative device stack angle embodiments can allow for rearranging components on the substrate 110 for at least improving routing efficiency.

A seventh example of a semiconductor device assembly including a cross-stack structure can be generally similar to the preceding examples, but can include multiple device stack pairs, each carrying a cross-stack structure. In the first, second, and third examples, the assemblies 100, 300, 500 each included a pair of the first and second device stacks 160, 170, 360, 370, 560, 570 with the single cross-stack structure 140 extending therebetween. In the seventh example, an assembly can include multiple pairs of device stacks on a single assembly substrate, with each device stack pair carrying a cross-stack structure.

For example, the assembly can include the first and second device stacks 160, 170, 360, 370, 560, 570 (e.g., a first device stack pair) at the assembly substrate and carrying the cross-stack structure 140. The assembly can further include a third and a fourth device stack (e.g., a second device stack pair) at the assembly substrate and carrying an additional cross-stack structure. The assembly can include further additional device stack pairs (e.g., a third, a fourth, a fifth device stack pair, etc.), each carrying a cross-stack structure. Assemblies corresponding with the seventh example can benefit from increased processing capacity and/or operating speed provided by the additional devices within the device stacks. Further, these assemblies can benefit from additional surface area on the cross-stack structures for carrying the components 150 thereon, opening additional space on the substrate.

An eighth example of a semiconductor device assembly including a cross-stack structure can be generally similar to the fourth example implemented in one of the preceding examples. That is, like the fourth example, one of the assemblies of the preceding examples can include multiple cross-stack structures extending between a single device stack pair. For example, the assembly can include the first and second device stacks 160, 170 of the first example at the assembly substrate with the lower device sub-stacks 160a, 170a carrying a first cross-stack structure 140. The first and second device stacks 160, 170 can each further include (i) a middle device sub-stack carried by the first cross-stack structure 140, (ii) a second cross-stack structure carried by the middle device sub-stacks, and (iii) an upper device sub-stack carried by the second cross-stack structure. In some embodiments, the assembly can further include additional device sub-stacks and corresponding cross-stack structures. Assemblies corresponding with the eighth example can benefit from increased processing capacity and/or operating speed provided by the additional devices within the device sub-stacks. Further, these assemblies can benefit from additional surface area on the additional cross-stack structures for carrying the components 150 thereon, opening additional space on the substrate.

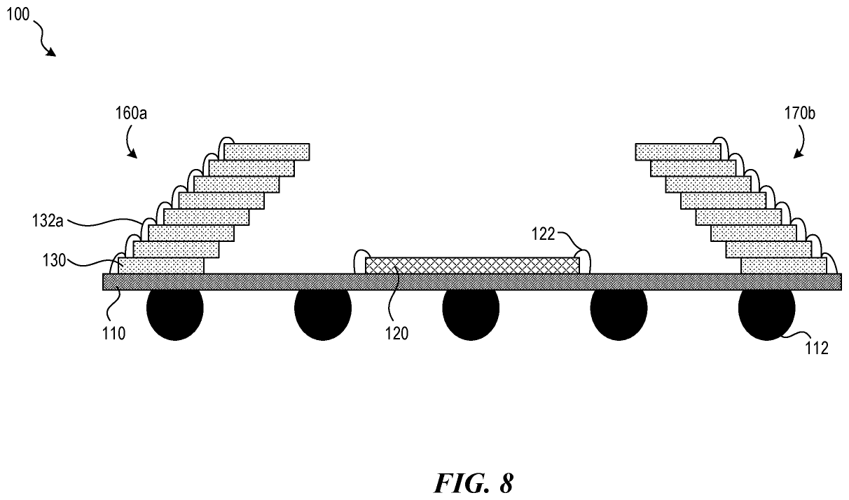

FIGS. 8-11 illustrate a process for manufacturing the assembly 100 of FIGS. 1 and 2 in accordance with some embodiments of the present technology. A similar process can be followed for manufacturing the assembly 300 of FIGS. 3 and 4, the assembly 500 of FIGS. 5 and 6, the assembly 700 of FIG. 7, and/or the assemblies of the above examples. The process illustrated by FIGS. 8-11 is intended for illustrative purposes and is non-limiting. In some embodiments, for example, the illustrated process can be accomplished with one or more additional operations not described, without one or more operations described, or with the operations in an alternative order.

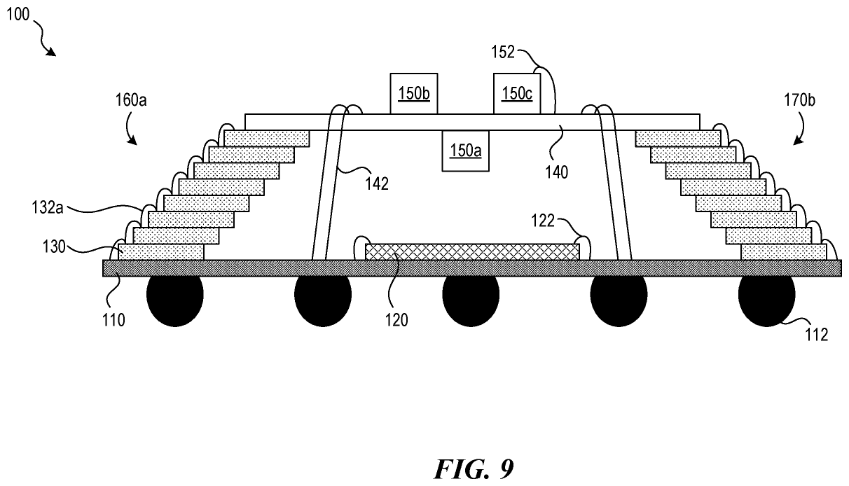

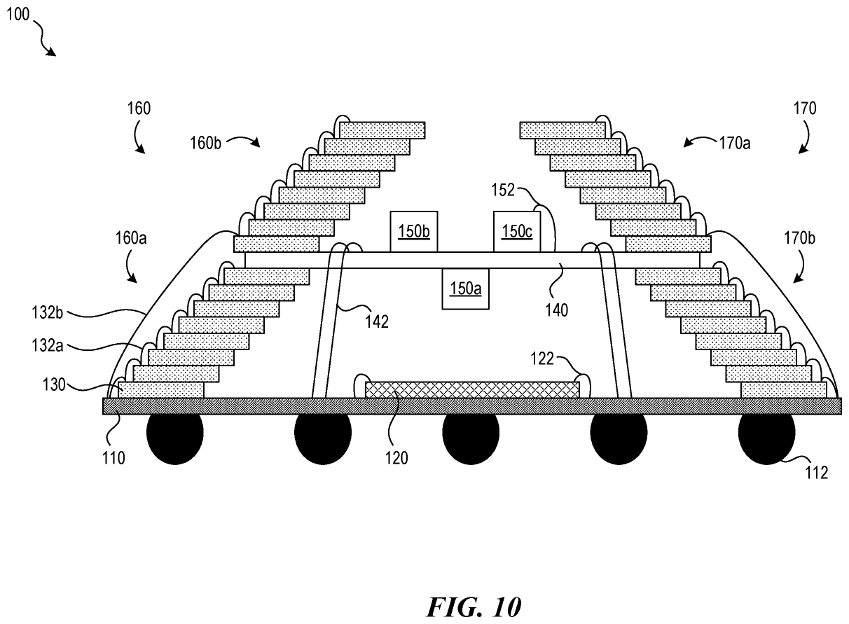

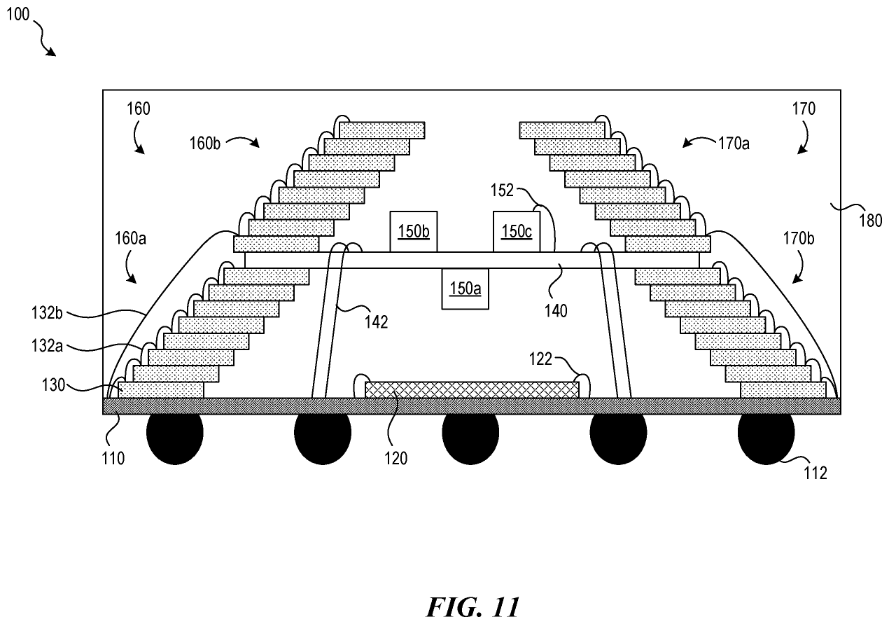

The illustrated process can generally include: (i) preparing the substrate 110, the controller 120, and the devices 130; coupling the controller 120 to the substrate 110; and forming the lower device sub-stacks 160a, 170a on the substrate 110 (FIG. 8); (ii) preparing the cross-stack structure 140 and coupling the cross-stack structure 140 to the lower device sub-stacks 160a, 170a (FIG. 9); (iii) preparing the devices 130 and forming the upper device sub-stacks 160b, 170b on the cross-stack structure 140 (FIG. 10); and (iv) encasing the assembly in the mold material 180 (FIG. 11). In some embodiments, one or more elements of the process can be performed by a single entity and/or at a single facility. For example, preparation of the substrate 110, the controller 120, the devices 130, and the cross-stack structure 140 can be performed by the same entity as the entity assembling these components. In some embodiment, one or more elements of the process can be performed by a first entity and/or at a first facility, and one or more elements can be performed by a second entity and/or at a second facility.

FIG. 8 illustrates the assembly 100 after (i) the substrate 110, the controller 120, and the devices 130 are prepared; (ii) the controller 120 is coupled to the substrate 110; (iii) the first and second lower device sub-stacks 160a, 170a are formed; and (iv) the wire bonds 122, 132a are formed from (e.g., between) the controller 120 and the devices 130 to the substrate 110, respectively. The substrate 110, the controller 120, and the devices 130 can be prepared using any suitable additive manufacturing process including, for example, sputtering, physical vapor deposition (“PVD”), electroplating, lithography, or any other similar process. Further, preparing can also include masking (e.g., dielectric, photoresist material) and/or etching processes intermixed with the additive processes.

Coupling the controller 120 to the substrate 110 can include any suitable semiconductor coupling method, such as solder bonding, hybrid bonding, surface bonding, adhesive bonding, and/or any similar, suitable method. The first and second lower device sub-stacks 160a, 170a can be formed by coupling (e.g., using the same or similar method(s)) the lowermost devices 130 to the substrate 110. Then, the subsequent device 130 can be coupled to the preceding device 130, shingled relative thereto, until the desired number of devices 130 is reached.

With the controller 120 coupled to the substrate 110 and the first and second lower device sub-stacks 160a, 170a formed, the wire bonds 122, 132a can be formed from (e.g., between) the controller 120 and the devices 130 to the substrate 110, respectively. The wire bonds 122, 132a can be formed using any suitable wire forming and bonding process to connect the wires between the substrate bond pads 114, the controller bond pads 124, and the device bond pads 134. In some embodiments, the wire bond 122 between the substrate 110 and the controller 120 can be formed before one or both of the first and second lower device sub-stacks 160a, 170a are formed. Similarly, the wire bond 132a between the substrate 110 and the devices 130 of the first or the second lower device sub-stacks 160a, 170a can be formed before the second or the first lower device sub-stacks 170a, 160a is formed, respectively.

FIG. 9 illustrates the assembly 100 after the cross-stack structure 140 is prepared and coupled to the first and the second lower device sub-stacks 160a, 170a. The cross-stack structure 140 can be prepared by forming the structure thereof and coupling the components 150 to the bottom and/or top surface of the formed structure. The structure can be formed using any suitable additive manufacturing process including, for example, sputtering, physical vapor deposition (“PVD”), electroplating, lithography, or any other similar process. Further, preparing can also include masking (e.g., dielectric, photoresist material) and/or etching processes intermixed with the additive processes.

The components 150 can be coupled to the structure using any suitable coupling method, such as solder bonding, hybrid bonding, surface bonding, adhesive bonding (e.g., DAF, FOW), and/or any similar, suitable method as for the components 150. The prepared cross-stack structure 140 can be coupled to the first and the second lower device sub-stacks 160a, 170a using the same and/or a similar method. One or more (or all) of the upper components 150b and/or the wire-bonded components 150c—components coupled to the top surface of the cross-stack structure 140—can be coupled to the cross-stack structure 140 subsequent to coupling the cross-stack structure 140 to the first and the second lower device sub-stacks 160a, 170a.

FIG. 10 illustrates the assembly 100 after (i) the devices 130 are prepared, (ii) the first and second upper device sub-stacks 160b, 170b are formed, and (iii) the wire bonds 132b are formed from (e.g., between) the devices 130 to the substrate 110. The devices 130 can be prepared using the same and/or a similar method to the devices 130 of the lower device sub-stacks 160a, 170a. The first and second upper device sub-stacks 160b, 170b can be formed by coupling the lowermost devices 130 to the cross-stack structure 140 using any suitable coupling method, such as solder bonding, hybrid bonding, surface bonding, adhesive bonding, and/or any similar, suitable method. Then, the subsequent device 130 can be coupled to the preceding device 130, shingled relative thereto, until the desired number of devices 130 is reached. With the first and second upper device sub-stacks 160b, 170b formed, the wire bonds 132b can be formed from (e.g., between) the devices 130 to the substrate 110. The wire bonds 132b can be formed using the same and/or a similar method to as used to form the wire bonds 132a of the lower device sub-stacks 160a, 170a.

FIG. 8 illustrates the assembly 100 after it is encased in the mold material 180. The assembly 100 can be encased in the mold material 180 by pouring a suitable mold material over the assembly 100, or by dipping the assembly 100 therein, and allowing the mold material 180 to cure. In some embodiments, a cutting and/or etching operation may be included to form uniform edges and/or sides of the assembly 100. When, like the assembly 700 of example four, the assembly 100 includes one or more additional cross-stack structures and device stack sub-stacks; or when the assembly includes one or more additional device stacks and/or device stack pairs, these additional elements can be prepared, coupled, and/or formed on the assembly 100 prior to encasing with the mold material 180.

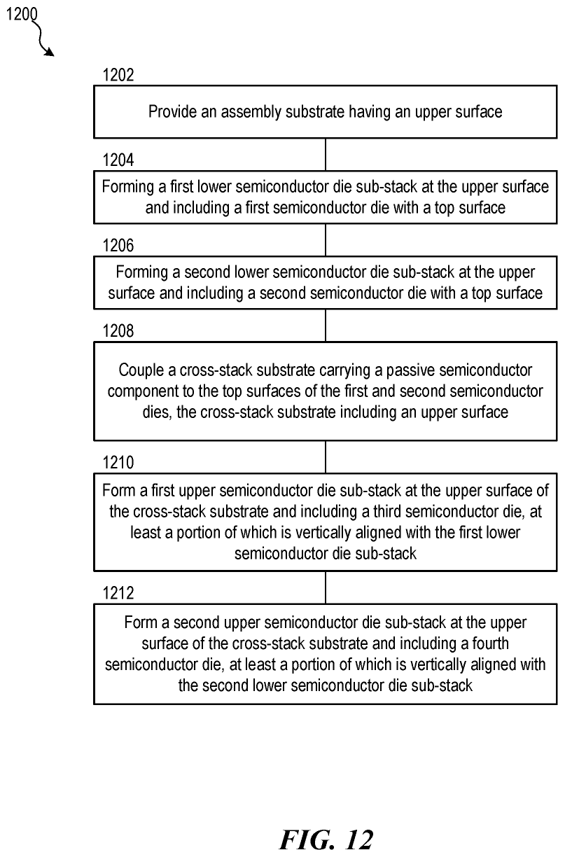

FIG. 12 is a flow diagram illustrating a process 1200 for producing a semiconductor device assembly, in accordance with some embodiments of the present technology. For example, the process 1200 can be used to produce at least the assembly 100 of FIGS. 1 and 2, the assembly 300 of FIGS. 3 and 4, the assembly 500 of FIGS. 5 and 6, the assembly 700 of FIG. 7, and/or one of the preceding examples. The operations of process 1200 are intended for illustrative purposes and are non-limiting. In some embodiments, for example, the process 1200 can be accomplished with one or more additional operations not described, without one or more of the operations described, or with operations described and/or not described in an alternative order.

As shown in FIG. 12, the process 1200 can include: providing an assembly substrate having an upper surface (process portion 1202); forming a first lower semiconductor die sub-stack at the upper surface and including a first semiconductor die with a top surface (process portion 1204); forming a second lower semiconductor die sub-stack at the upper surface and including a second semiconductor die with a top surface (process portion 1206); coupling a cross-stack substrate carrying a passive semiconductor component to the top surfaces of the first and second semiconductor dies, the cross-stack substrate including an upper surface (process portion 1208); forming a first upper semiconductor die sub-stack at the upper surface of the cross-stack substrate and including a third semiconductor die, at least a portion of which is vertically aligned with the first lower semiconductor die sub-stack (process portion 1210); and forming a second upper semiconductor die sub-stack at the upper surface of the cross-stack substrate and including a fourth semiconductor die, at least a portion of which is vertically aligned with the second lower semiconductor die sub-stack (process portion 1212).

In some embodiments, one or more of the process portions 1202-1212 can be performed in a single facility. For example, preparation and fabrication of (e.g., providing) the assembly substrate, the semiconductor dies, and the cross-stack substrate; and coupling the same together can be performed by a single entity or at a single facility. In some embodiments, one or more of the process portions 1202-1212 can be performed at multiple facilities. For example, the preparation and fabrication of (e.g., providing) the assembly substrate, the semiconductors, and/or the cross-stack substrate can be performed by a first entity or at a first facility; and coupling the same together can be performed by a second entity or at a second facility, among other shared process performance arrangements.

Providing the assembly substrate having the upper surface (process portion 1202) can include preparing an assembly substrate using any suitable additive manufacturing process including, for example, sputtering, physical vapor deposition (“PVD”), electroplating, lithography, or any other similar process to form the assembly substrate. Further, preparing can also include masking (e.g., dielectric, photoresist material) and/or etching processes intermixed with the additive processes.

Forming the first and second lower semiconductor die sub-stacks at the upper surface of the assembly substrate (process portions 1204, 1206) can include (i) preparing semiconductor dies, and (ii) coupling the semiconductor dies to the upper surface. The semiconductor dies can be prepared using the same and/or similar processes as preparing the assembly substrate. The prepared semiconductor dies can be coupled to the upper surface using any suitable coupling method, such as solder bonding, hybrid bonding, surface bonding, adhesive bonding, and/or any similar, suitable method. When the first and second lower semiconductor die sub-stacks include one or more additional semiconductor dies, the additional semiconductor dies can be coupled to, and shingled relative to a preceding semiconductor die. Further, wire bonds can be formed between one or more of the semiconductor dies and the assembly substrate.

Coupling a cross-stack substrate carrying the passive semiconductor component to the top surfaces of the first and second semiconductor dies (process portion 1208) can include (i) preparing the cross-stack substrate, and (ii) coupling the cross-stack substrate to the semiconductor dies. The cross-stack substrate can be prepared using the same and/or similar processes as preparing the assembly substrate. The prepared cross-stack substrate can be coupled to the semiconductor dies using any suitable coupling method, such as solder bonding, hybrid bonding, surface bonding, adhesive bonding, and/or any similar, suitable method.

Forming the first and second upper semiconductor die sub-stacks at the upper surface of the cross-stack substrate (process portions 1210, 1212) can include (i) preparing semiconductor dies, and (ii) coupling the semiconductor dies to the upper surface. The semiconductor dies can be prepared using the same and/or similar processes as preparing the assembly substrate. The prepared semiconductor dies can be coupled to the upper surface using any suitable coupling method, such as solder bonding, hybrid bonding, surface bonding, adhesive bonding, and/or any similar, suitable method. When the first and second upper semiconductor die sub-stacks include one or more additional semiconductor dies, the additional semiconductor dies can be coupled to, and shingled relative to a preceding semiconductor die. Further, wire bonds can be formed between one or more of the semiconductor dies and the assembly substrate. Further still, when the assembly includes one or more additional cross-stack substrates, and the first and second die stacks include one or more additional die sub-stacks, the additional cross-stack substrates and die sub-stacks can be prepared and coupled to the assembly.

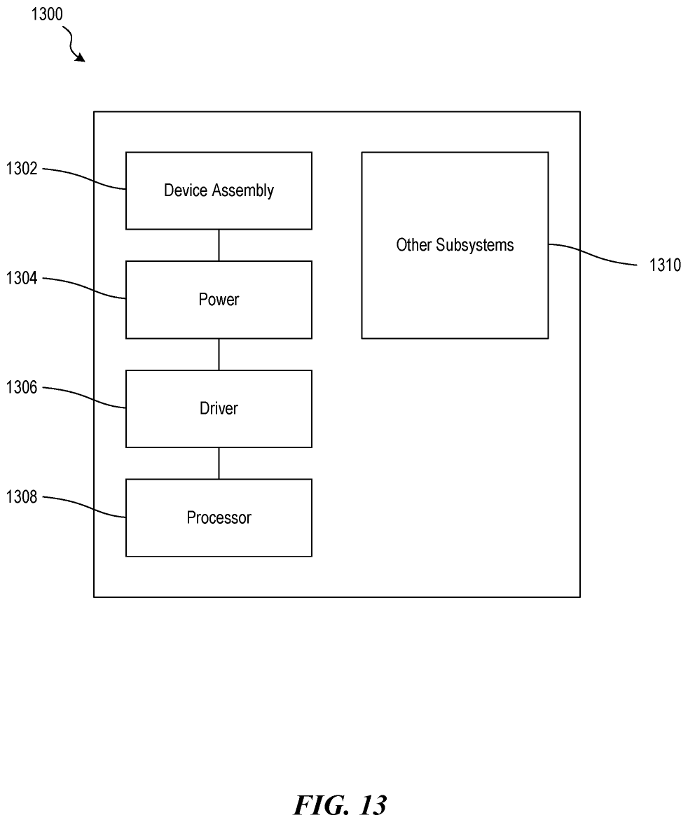

Any one of the semiconductor devices, dies, and/or assemblies described above with reference to FIGS. 1-12 can be incorporated into any of a myriad of larger and/or more complex systems, a representative example of which is system 1300 shown schematically in FIG. 13. The system 1300 can include a semiconductor device assembly 1302 (e.g., the assembly 100 of FIGS. 1 and 2, the assembly 300 of FIGS. 3 and 4, the assembly 500 of FIGS. 5 and 6, the assembly 700 of FIG. 7), a power source 1304, a driver 1306, a processor 1308, and/or other subsystems or components 1310. The semiconductor device assembly 1302 can include features generally similar to those of the semiconductor devices and assemblies described above with reference to FIGS. 1-9. The resulting system 1300 can perform any of a wide variety of functions, such as memory storage, data processing, or other suitable functions. Accordingly, representative systems 1300 can include, without limitation, hand-held devices (e.g., mobile phones, tablets, digital readers, and digital audio players), computers, vehicles, appliances, and other products. Components of the system 1300 may be housed in a single unit or distributed over multiple, interconnected units (e.g., through a communications network). The components of the system 1300 can also include remote devices and any of a wide variety of computer readable media.

For example, the assembly 1302 can be a semiconductor device assembly comprising an assembly substrate including an upper surface, a first and second die stack at the upper surface, and a cross-stack substrate spaced from the upper surface. The first and second die stacks can each include multiple semiconductor dies in electric communication with the assembly substrate, and the cross-stack substrate can be coupled to and extending between a first and a second semiconductor die of the first and second die stacks, respectively. A passive semiconductor component can be carried by the cross-stack substrate, and can be in electric communication with the assembly substrate. Further, the passive semiconductor component can be in electric communication with the first semiconductor die of the first die stack exclusively via the assembly substrate.

In some embodiments, the passive semiconductor component is further in electric communication with the second semiconductor die of the first die stack.

In some embodiments, the passive semiconductor component is further in electric communication with the first or second semiconductor die of the second die stack.

In some embodiments, the multiple semiconductor dies of the first die stack are shingled toward the second die stack. In some of these embodiments, the multiple semiconductor dies of the second die stack are shingled toward the first die stack.

In some embodiments, the multiple semiconductor dies of the first die stack are shingled along a first direction, and the second die stack is separated from the first die stack along a first distance perpendicular to the first direction.

In some embodiments, the cross-stack substrate is a first cross-stack substrate, and the assembly further comprises a second cross-stack substrate spaced from the upper surface of the assembly substrate and from the first cross-stack substrate and extending between the first and second die stacks, wherein the second cross-stack substrate is coupled between a third and fourth semiconductor die of the first and second die stacks, respectively.

In some embodiments, the passive semiconductor component is in electric communication with the assembly substrate via (i) a first interconnection between the passive semiconductor component and the cross-stack substrate, (ii) the cross-stack substrate, and (iii) a second interconnection between the cross-stack substrate and the assembly substrate.

In some embodiments the assembly further comprises a controller at the upper surface of the assembly substrate, wherein the controller is in electric communication with the assembly substrate.

In some embodiments, the controller is further in electric communication with the passive semiconductor component exclusively via the assembly substrate.

As a further example, the assembly 1302 can comprise an assembly substrate including an upper surface, a first and second die stack at the upper surface, and a cross-stack substrate spaced from the upper surface and including a top and bottom surface. The first and second die stacks can each include multiple semiconductor dies, and the cross-stack substrate can be coupled to and extending between a first and a second semiconductor die of the first and second die stacks, respectively. A top passive semiconductor component can be carried by the top surface of the cross-stack substrate, and a bottom passive semiconductor component can be carried by the bottom surface of the cross-stack substrate.

In some embodiments, each of the first and second die stacks includes a lower die sub-stack and an upper die sub-stack, wherein the first semiconductor die of the first and second die stacks is one of eight semiconductor dies of the lower die sub-stacks, respectively, and wherein the second semiconductor die of the first and second die stacks is one of eight semiconductor dies of the upper die sub-stacks.

In some embodiments, the top passive semiconductor component is in electric communication with the assembly substrate, wherein the first die of the first die stack is in electric communication with the assembly substrate, and wherein the first die is in electric communication with the top passive semiconductor component exclusively via the assembly substrate.

In some embodiments, the top passive semiconductor component is in electric communication with the cross-stack substrate via a wire bond interconnection.

In some embodiments, the top passive semiconductor component is in electric communication with the cross-stack substrate via a solder bond interconnection.

In some embodiments, the bottom passive semiconductor component is in electric communication with the cross-stack substrate via a hybrid bond interconnection.

In some embodiments, the top passive semiconductor component is a first top passive semiconductor component and the assembly further comprises a second top passive semiconductor component at the top surface of the cross-stack substrate.

In some embodiments, the bottom passive semiconductor component is a first bottom passive semiconductor component and the assembly further comprises a second bottom passive semiconductor component at the bottom surface of the cross-stack substrate.

A method for manufacturing the assembly 1302 can comprise providing an assembly substrate having an upper surface, forming a first lower semiconductor die sub-stack at the upper surface and including a first semiconductor die with a top surface, and forming a second lower semiconductor die sub-stack at the upper surface and including a second semiconductor die with a top surface. Next, a cross-stack substrate carrying a passive semiconductor component can be coupled to the top surfaces of the first and second semiconductor dies. A first upper semiconductor die sub-stack can be formed at an upper surface of the cross-stack substrate, including a third semiconductor die, at least a portion of which is vertically aligned with the first lower semiconductor die sub-stack; and a second upper semiconductor die sub-stack can be formed at the upper surface of the cross-stack substrate, including a fourth semiconductor die, at least a portion of which is vertically aligned with the second lower semiconductor die sub-stack. Further, a mold material can be provided over the first and second lower semiconductor die sub-stacks, the cross-stack substrate, and the first and second upper semiconductor die sub-stacks.

Specific details of several embodiments of semiconductor devices, and associated systems and methods, are described above. A person skilled in the relevant art will recognize that suitable stages of the methods described herein can be performed at the wafer level or at the die level. Therefore, depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, chemical-mechanical planarization, or other suitable techniques.

The devices discussed herein, including memory devices, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOS), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

As used herein, including in the claims, “and/or” as used in a list of items (for example, a list of items prefaced by a phrase such as “at least one of” or “one or more of”) indicates an inclusive list such that, for example, a list of at least one of A, B, and/or C means: A or B or C; or AB or AC or BC; or ABC (i.e., A and B and C). As used herein, the terms “vertical,” “lateral,” “upper,” “lower,” “above,” “below,” “top,” and “bottom” can refer to relative directions or positions of features in the semiconductor devices in view of the orientation shown in the figures. For example, “upper” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation. It should be noted that the methods described above describe possible implementations, and that the operations and the steps may be rearranged or otherwise modified and that other implementations are possible. Furthermore, embodiments from two or more of the methods may be combined.

From the foregoing, it will also be appreciated that various modifications may be made without deviating from the disclosure or the technology. For example, one of ordinary skill in the art will understand that various components of the technology can be further divided into subcomponents, or that various components and functions of the technology may be combined and integrated. In addition, certain aspects of the technology described in the context of particular embodiments may also be combined or eliminated in other embodiments. Although advantages associated with certain embodiments of the technology have been described in the context of those embodiments, other embodiments may also exhibit such advantages, and not all embodiments need necessarily exhibit such advantages to fall within the scope of the technology. Accordingly, the disclosure and associated technology can encompass other embodiments not expressly shown or described herein.

We claim:

1. A semiconductor device assembly, comprising:
an assembly substrate including an upper surface;
a first and second die stack at the upper surface, each including multiple semiconductor dies in electric communication with the assembly substrate;
a cross-stack substrate spaced from the upper surface and coupled to and extending between the first and second die stacks, wherein the cross-stack substrate is coupled between a first and second semiconductor die of the first and second die stacks, respectively; and
a passive semiconductor component carried by the cross-stack substrate and in electric communication with the assembly substrate, wherein the passive semiconductor component is further in electric communication with the first semiconductor die of the first die stack exclusively via the assembly substrate.

2. The semiconductor device assembly of claim 1, wherein the passive semiconductor component is further in electric communication with the second semiconductor die of the first die stack.

3. The semiconductor device assembly of claim 1, wherein the passive semiconductor component is further in electric communication with the first or second semiconductor die of the second die stack.

4. The semiconductor device assembly of claim 1, wherein the multiple semiconductor dies of the first die stack are shingled toward the second die stack.

5. The semiconductor device assembly of claim 4, wherein the multiple semiconductor dies of the second die stack are shingled toward the first die stack.

6. The semiconductor device assembly of claim 1, wherein the multiple semiconductor dies of the first die stack are shingled along a first direction, and the second die stack is separated from the first die stack along a first distance perpendicular to the first direction.

7. The semiconductor device assembly of claim 1, wherein the cross-stack substrate is a first cross-stack substrate, and the assembly further comprises a second cross-stack substrate spaced from the upper surface of the assembly substrate and from the first cross-stack substrate and extending between the first and second die stacks, wherein the second cross-stack substrate is coupled between a third and fourth semiconductor die of the first and second die stacks, respectively.

8. The semiconductor device assembly of claim 1, wherein the passive semiconductor component is in electric communication with the assembly substrate via (i) a first interconnection between the passive semiconductor component and the cross-stack substrate, (ii) the cross-stack substrate, and (iii) a second interconnection between the cross-stack substrate and the assembly substrate.

9. The semiconductor device assembly of claim 1 further comprising a controller at the upper surface of the assembly substrate, wherein the controller is in electric communication with the assembly substrate.

10. The semiconductor device assembly of claim 9, wherein the controller is further in electric communication with the passive semiconductor component exclusively via the assembly substrate.

11. A semiconductor device assembly, comprising:
an assembly substrate including an upper surface;
a first and second die stack at the upper surface, each including multiple semiconductor dies;
a cross-stack substrate spaced from the upper surface and coupled to and extending between the first and second die stacks, wherein the cross-stack substrate is coupled between a first and second semiconductor die of the first and second die stacks, respectively, and wherein the cross-stack substrate includes a top and bottom surface;
a top passive semiconductor component carried by the top surface of the cross-stack substrate; and
a bottom passive semiconductor component carried by the bottom surface of the cross-stack substrate.

12. The semiconductor device assembly of claim 11, wherein each of the first and second die stacks includes a lower die sub-stack and an upper die sub-stack, wherein the first semiconductor die of the first and second die stacks is one of eight semiconductor dies of the lower die sub-stacks, respectively, and wherein the second semiconductor die of the first and second die stacks is one of eight semiconductor dies of the upper die sub-stacks.

13. The semiconductor device assembly of claim 11, wherein the top passive semiconductor component is in electric communication with the assembly substrate, wherein the first die of the first die stack is in electric communication with the assembly substrate, and wherein the first die is in electric communication with the top passive semiconductor component exclusively via the assembly substrate.

14. The semiconductor device assembly of claim 11, wherein the top passive semiconductor component is in electric communication with the cross-stack substrate via a wire bond interconnection.

15. The semiconductor device assembly of claim 11, wherein the top passive semiconductor component is in electric communication with the cross-stack substrate via a solder bond interconnection.

16. The semiconductor device assembly of claim 11, wherein the bottom passive semiconductor component is in electric communication with the cross-stack substrate via a hybrid bond interconnection.

17. The semiconductor device assembly of claim 11, wherein the top passive semiconductor component is a first top passive semiconductor component and the assembly further comprises a second top passive semiconductor component at the top surface of the cross-stack substrate.

18. The semiconductor device assembly of claim 11, wherein the bottom passive semiconductor component is a first bottom passive semiconductor component and the assembly further comprises a second bottom passive semiconductor component at the bottom surface of the cross-stack substrate.

19. A method of manufacturing a semiconductor device assembly, comprising:
providing an assembly substrate having an upper surface;
forming a first lower semiconductor die sub-stack at the upper surface and including a first semiconductor die with a top surface;
forming a second lower semiconductor die sub-stack at the upper surface and including a second semiconductor die with a top surface;
coupling a cross-stack substrate carrying a passive semiconductor component to the top surfaces of the first and second semiconductor dies, the cross-stack substrate including an upper surface;
forming a first upper semiconductor die sub-stack at the upper surface of the cross-stack substrate and including a third semiconductor die, at least a portion of which is vertically aligned with the first lower semiconductor die sub-stack; and
forming a second upper semiconductor die sub-stack at the upper surface of the cross-stack substrate and including a fourth semiconductor die, at least a portion of which is vertically aligned with the second lower semiconductor die sub-stack.

20. The method of claim 19 further comprising providing a mold material over the first and second lower semiconductor die sub-stacks, the cross-stack substrate, and the first and second upper semiconductor die sub-stacks.
